(19) United States
(12) Patent Application Publication
(10) Pub. No.: US 2026/0324056 A1
(43) Pub. Date: Oct. 15, 2026

(54) SEMICONDUCTOR DEVICE

(71) Applicant: Taiwan Semiconductor Manufacturing Company, Ltd., Hsinchu (TW)

(72) Inventors: Yu-Hung YEH, Hsinchu (TW); Jui-Chien HUANG, Hsinchu (TW); Wun-Jie LIN, Hsinchu (TW); Jam-Wem LEE, Hsinchu (TW)

(21) Appl. No.: 19/281,471

(22) Filed: Jul. 25, 2025

Related U.S. Application Data
(60) Provisional application No. 63/787,266, filed on Apr. 11, 2025.

(51) Int. Cl. H10D 84/80; H01L 23/528; H10D 8/00; H10D 8/01; H10D 30/00; H10D 30/01; H10D 62/10; H10D 62/60; H10D 62/832; H10D 84/01

(52) U.S. Cl. CPC H10D 84/811; H10D 8/045; H10D 8/411; H10D 30/0191; H10D 30/502; H10D 62/103; H10D 62/60; H10D 62/832; H10D 84/0107; H10W 20/435

(57) ABSTRACT

A semiconductor device structure comprises, in some embodiments, a first gate structure formed under a first semiconductor stack; a first contact formed beside the first gate structure; a first implant region in the first semiconductor stack over the first contact; a second semiconductor stack formed over the first semiconductor stack; a second gate structure formed over the second semiconductor stack; a second contact formed beside the second gate structure; and a second implant region in the second semiconductor stack below the second contact, wherein a projection of the first implant region is separated from a projection of the second implant region in a top view.

### CROSS REFERENCE TO RELATED APPLICATION

This application claims the benefit of U.S. Provisional Patent Application No. 63/787,266, filed Apr. 11, 2025, the disclosure of which is incorporated herein by reference in its entirety.

### BACKGROUND

To fabricate a vertical diode in a CFET (complementary FET) process, the implantation techniques of the CMOS process can be utilized. However, the constraints on sheet distance may affect the diode's performance, including its breakdown voltage.

### SUMMARY

In some embodiments, a diode includes a in the complementary FET (CFET)

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically illustrates a diode according to some embodiments.

FIG. 2 schematically illustrates a diode according to certain additional embodiments.

FIG. 3 schematically illustrates a diode according to certain additional embodiments.

FIG. 4 schematically illustrates a diode according to certain additional embodiments.

FIG. 5 schematically illustrates a configuration including multiple diodes according to certain additional embodiments.

FIGS. 6, 7A-H, K, L, and M, and 7A′-H′, K′, L′, and M′ schematically illustrate the steps in forming the diode shown in FIG. 2 and simultaneously forming a pair of complementary field-effect transistor (CFET) according to certain additional embodiments.

FIGS. 8A and 8B outlines a process of forming a diode and simultaneously forming at least one field-effect transistor (FET, such as a CFET) according to certain additional embodiments.

FIG. 9 schematically illustrates a bipolar junction transistor (BJT) according to certain additional embodiments

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Diodes are used in certain circuits implemented by integrated circuits (ICs). In such ICs, diodes can be constructed in a semiconductor layer. Other semiconductor devices, such transistors, can be formed in the same layer as the diodes. In some IC structures with three-dimensional (3D) semiconduction devices, such as complementary field-effect transistors (CFETs), a diode, such as PIN diode can be formed in the dimension in the thickness direction of the semiconductor layer, e.g., with the p-region and n-region disposed opposite each other across at least a portion of the thickness of the semiconductor layer. The semiconductor portion intervening the p-region and n-region can be intrinsic or lightly doped.

In some embodiments, a diode includes a p-region and an n-region, both disposed in a semiconductor layer having a top surface and a bottom surface. The top and bottom surfaces of the semiconductor layer extend laterally substantially in two dimensions (e.g., in the x-and y-directions) and are oriented along the third dimension (e.g., z-direction). The p-region and n-region are disposed at different distances from the top surface (or bottom surface). That is, the top and bottom surfaces are offset from each other in the third dimension, e.g., along the z-direction. For example, one of the p-region and n-region can be disposed at the top surface, and the other one of the p-region and n-region can be disposed at the bottom surface. In some embodiments, the top and bottom surfaces are additionally offset from each other in the first and/or second dimensions, e.g., along the x-and/or y-directions.

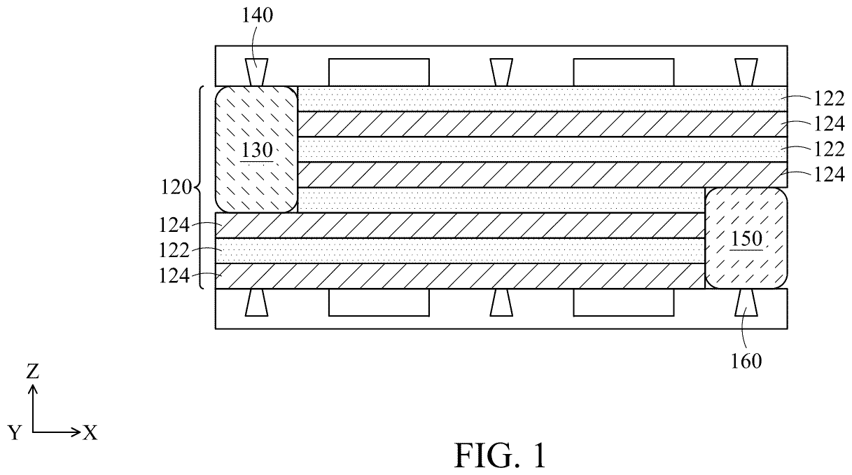

An example of a diode according to some embodiments is schematically shown in FIG. 1. The diode 100 in this example includes semiconductor layer 120 extending laterally, i.e., in the x-and y-directions. An n-region, in this example a heavily-doped N⁺-region 130 is formed in the semiconductor layer 120 and positioned at the top surface of the semiconductor layer 120. A p-region, in this example a heavily-doped P⁺-region 150 is formed in the semiconductor layer 120 and positioned at the bottom surface of the semiconductor layer 120. The diode 100 further includes a first conductive contact 140 connected to the N⁺-region 130, and a second conductive contact 160 connected to the P⁺-region 150, for connecting the diode 100 to other devices.

In this example, in addition to being offset from each other in the vertically, or in the z-direction, the N⁺-region 130 and the P⁺-region 150 are offset from each other in the laterally, in this case in the x-direction.

The semiconductor layer 120 in the diode 100 in the example includes stacked semiconductor sheets 122,124, with alternating compositions. In this example, the semiconductor sheets 122 are silicon (Si), and the semiconductor sheets 122 are made of a silicon-germanium alloy (SiGe). Other compositions can be used depending on application. Such a structure can be used, for example, in fabricating various devices, including, for example, gate-all-around (GAA) transistors and CFETs, as will be shown in other examples in the present disclosure.

With both a vertical and lateral offsets between the p-and n-regions of a diode in certain embodiments disclosed in the present disclosure, certain drawbacks of diodes with the p-and n-regions disposed directly vertically opposite each other may be mitigated. For example, in some IC manufacturing processes, the p-region and n-region of a diode are formed by ion implantation. Limitations on the ability to control implantation depth may lead to unacceptable uncertainty in the distance between the p-region and n-region (p-n spacing), or even punch-through. Furthermore, given a number of semiconductor sheets in the semiconductor layer, the design choices can be limited, given the p-n spacing requirements, for diodes with directly vertically opposing p-and n-regions. Diodes with “diagonally” (both vertically and laterally) offset p-and n-regions can provide wider ranges of design choices and less adverse effects of process variation.

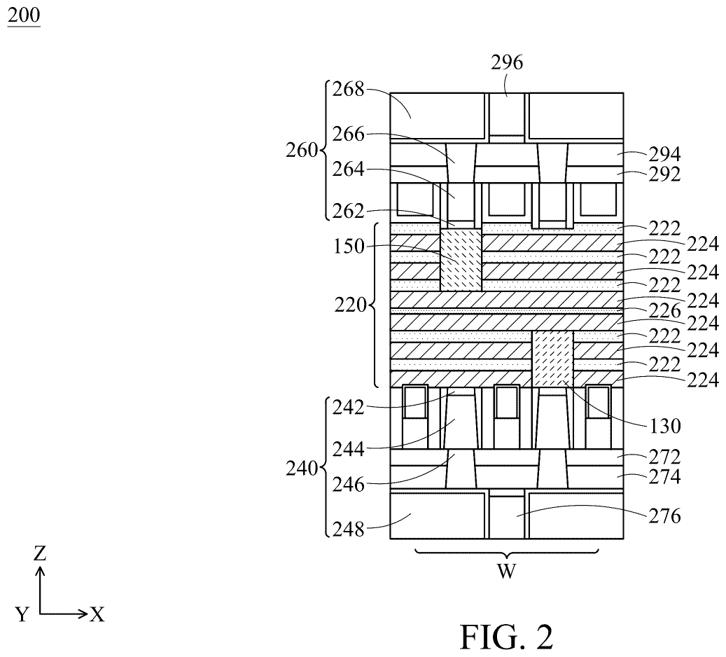

Referring to FIG. 2, a diode 200 fabricated in a semiconductor layer 220 in a process that is compatible with CFETs, as described below. The diode 200 includes a frontside, or bottom, electrode 130, in this example a heavily-doped N⁺-region that is formed in the semiconductor layer 220 and positioned at the bottom surface of the semiconductor layer 220. The diode 200 further includes a backside, or top, electrode, which, in this example a heavily-doped P⁺-region 150 that is formed in the semiconductor layer 220 and positioned at the top surface of the semiconductor layer 220. The diode 100 further includes a first conductive contact structure 240 connected to the N⁺-region 130, and a second conductive contact structure 260 connected to the P⁺-region 150, for connecting the diode 100 to other devices. The first conductive contact structure 240 can include any suitable conductive material or materials; in this example, it includes a metal-semiconductor alloy layer 242, vias 244, 246 and a contact pad 248. Similarly, the second conductive contact structure 260 can include any suitable conductive material or materials; in this example, it includes a metal-semiconductor alloy layer 262, vias 264, 266 and a contact pad 268. The diode 200 in this example further includes isolation regions 272, 274, 276 at the bottom, or frontside, and isolation regions 292, 294, 296 at the top, or backside.

The semiconductor layer 220 in this example is similar to the semiconductor layer 120 shown in FIG. 1 and includes stacked sheet of semiconductor layers of alternating composition. For example, sheets 122 may be Si, and sheets 124 may be SiGe. The semiconductor layer 220 in this example, however, further includes a dummy semiconductor layer 226, which in some embodiments is germanium (Ge) or SiGe with a higher Ge content than the SiGe sheets 124. The sheets 122, 124 below the dummy semiconductor layer 226 (frontside sheets) can be substantially intrinsic, or at least some of the frontside sheets, such as the Si sheets 122, can be doped, such as n-doped. Likewise, the sheets 122, 124 above the dummy semiconductor layer 226 (backside sheets) can be substantially intrinsic, or at least some of the frontside sheets, such as the Si sheets 122, can be doped, such as p-doped.

In the example shown in FIG. 2, the diode 200 nominally occupies a with, W, that is twice the spacing between the laterally neighboring vias 244, 246 and 264, 266. In some embodiments, the lateral inter-via spacing for the diodes (e.g., diode 200) is the same as, or multiple of, the lateral spacing between spacing between vias for connections to the sources or drains of the transistors, such as CFETs, that are fabricated in the same IC. The processes (including tooling) of fabricating the diode are thus made more compatible with those of fabricating other devices, such as transistors. Certain manufacturing and/or design efficiencies may thus be achieved.

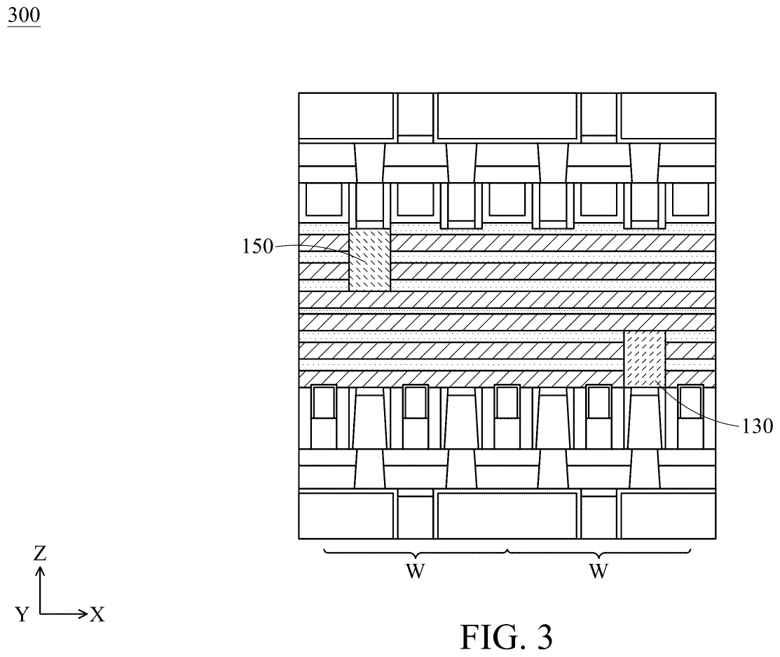

In certain other embodiments, such as the example illustrated in FIG. 3, a diode 300 is similar to the diode 200 illustrated in FIG. 2 but is wider than diode 200. The n-and p-regions 130, 150 in this example are three (3) via-spacings apart from each other laterally instead of one spacing as for the diode 200. The increased distance may provide the advantage of reducing the probability of junction breakdown and reducing parasitic capacitance.

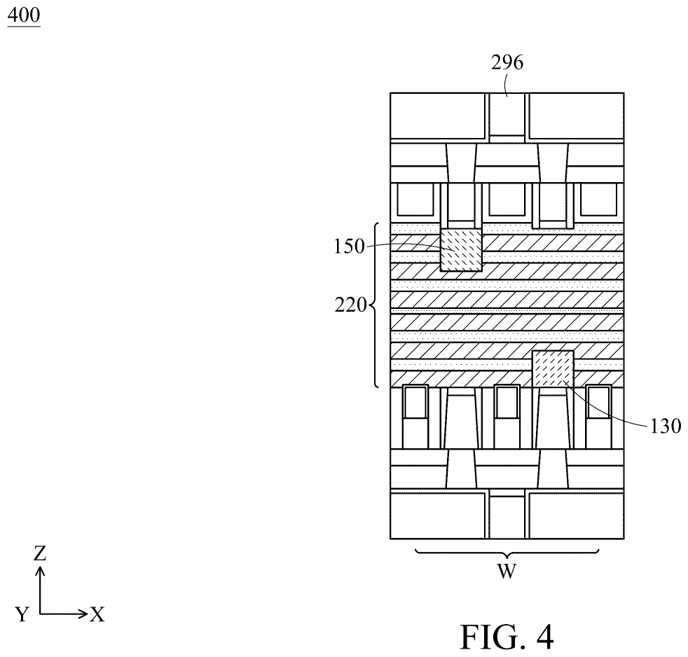

In certain further embodiments, such as the example illustrated in FIG. 4, a diode 400 is similar to the diode 200 illustrated in FIG. 2 but with smaller sizes of the n-and p-regions 130, 150. Sizes can be selected depending on the desired electrical characteristics of the diode. Variations in sizes of the n-and/or p-regions can be achieved in any suitable manner. For example, where the n-and/or p-regions are formed by ion implantation, the implantation energy and/or dosage and/or number of implantation cycles may be selected to arrive at the desired characteristics of the n-and/or p-regions.

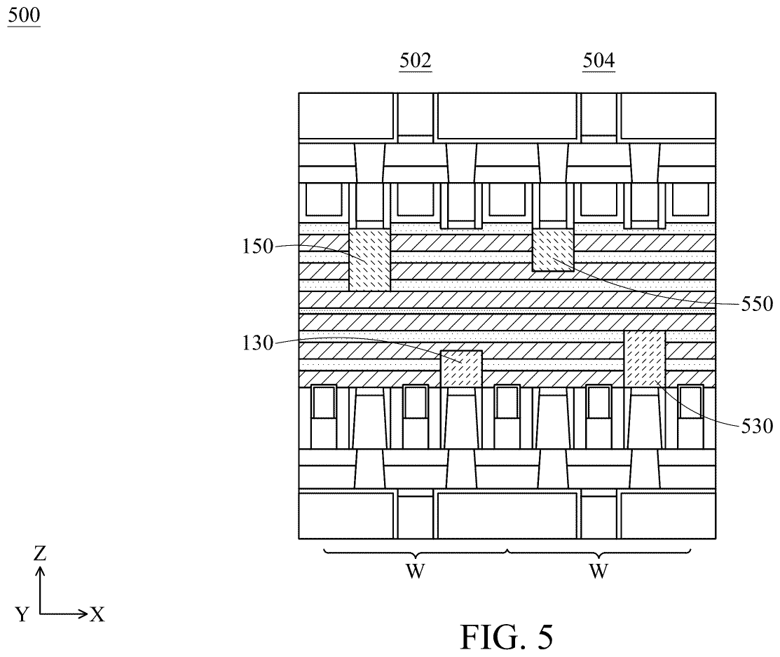

In certain further embodiments, such as the example illustrated in FIG. 5, the device 500 is similar to the diode 300 illustrated in FIG. 3 but includes two diodes 502, 504, each with different sizes between the n-region and the p-region. In diode 502, the p-region 130 is smaller in size than the respective n-region 150; in diode 504, the p-region 530 is larger in size than the respective n-region 550. Such a configuration can be obtained by more complex processes than for uniform-sized n-and p-regions. For example, for n-and/or p-regions formed by ion implantation, multiple implantation cycles may be needed for any given side (frontside or backside), with the smaller n-and/or p-regions formed first and then blocked from further implantations for forming the larger n-and/or p-regions.

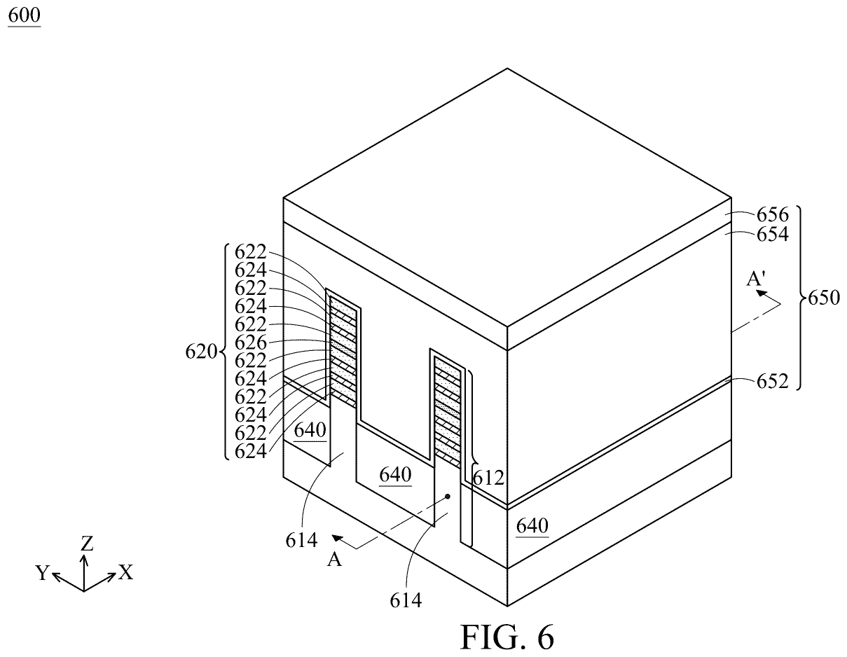

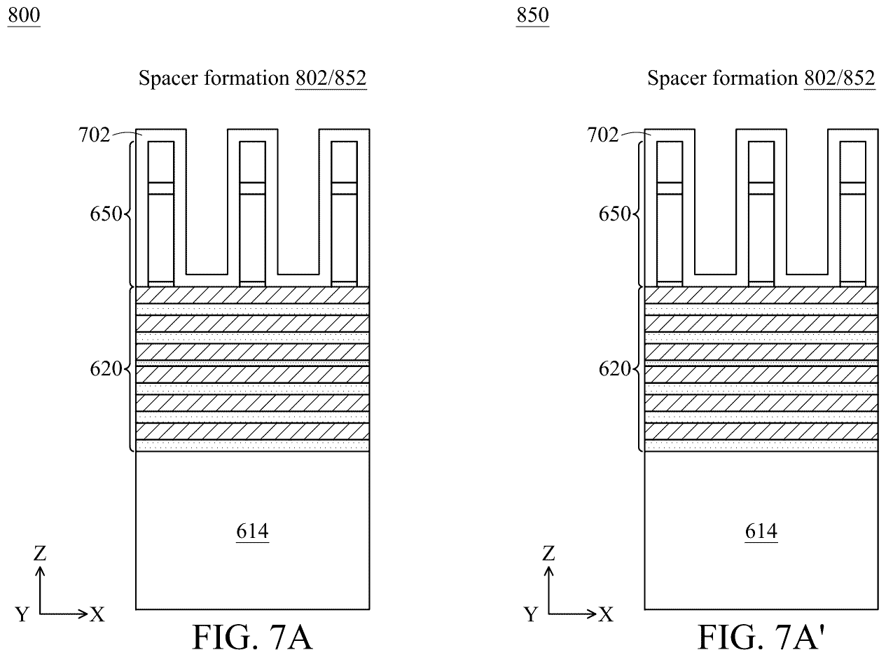

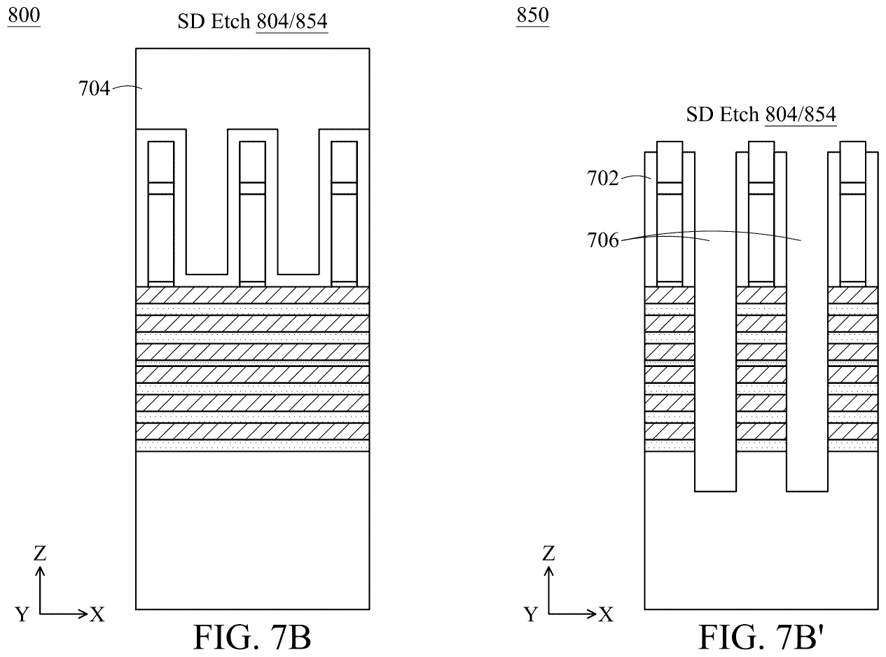

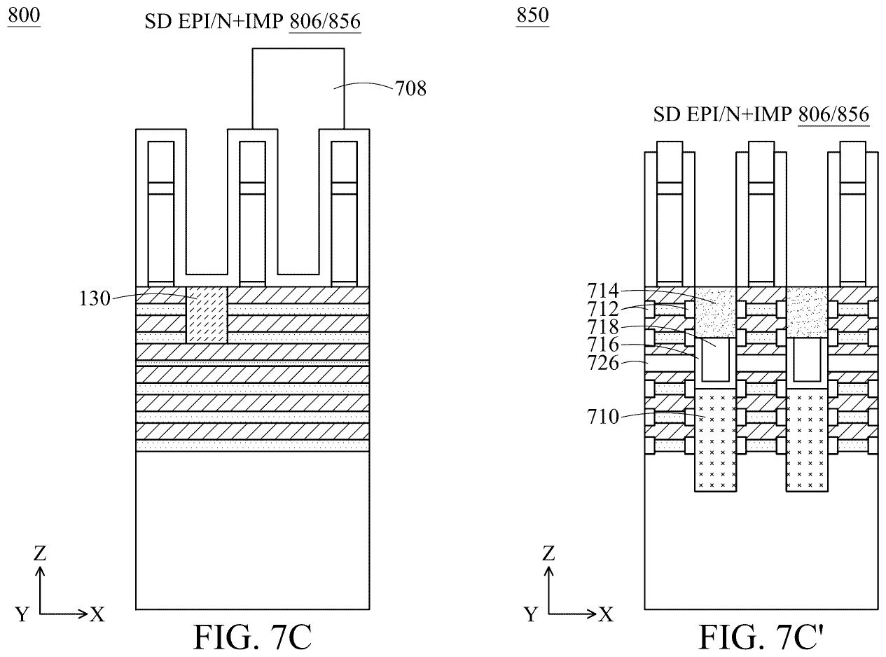

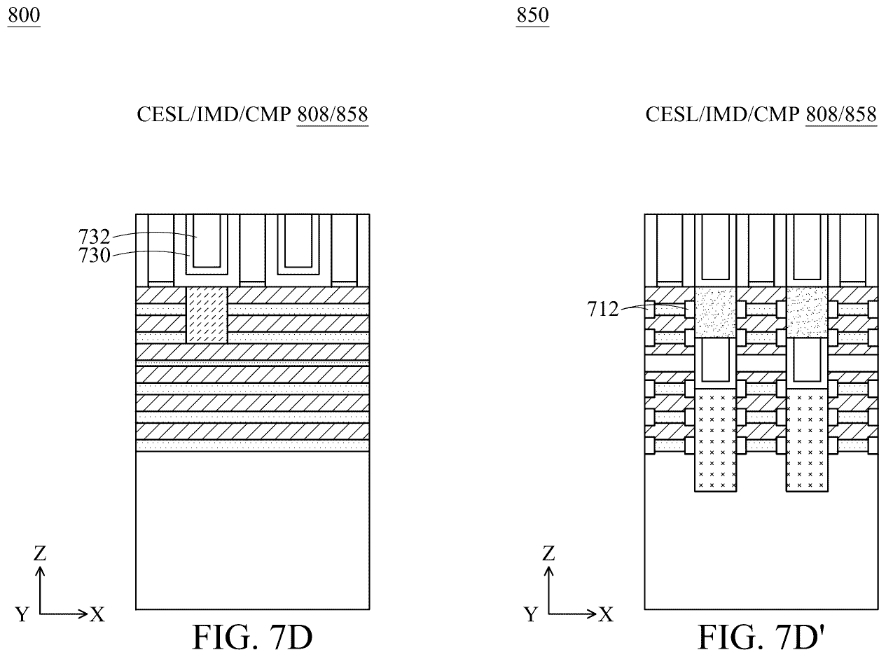

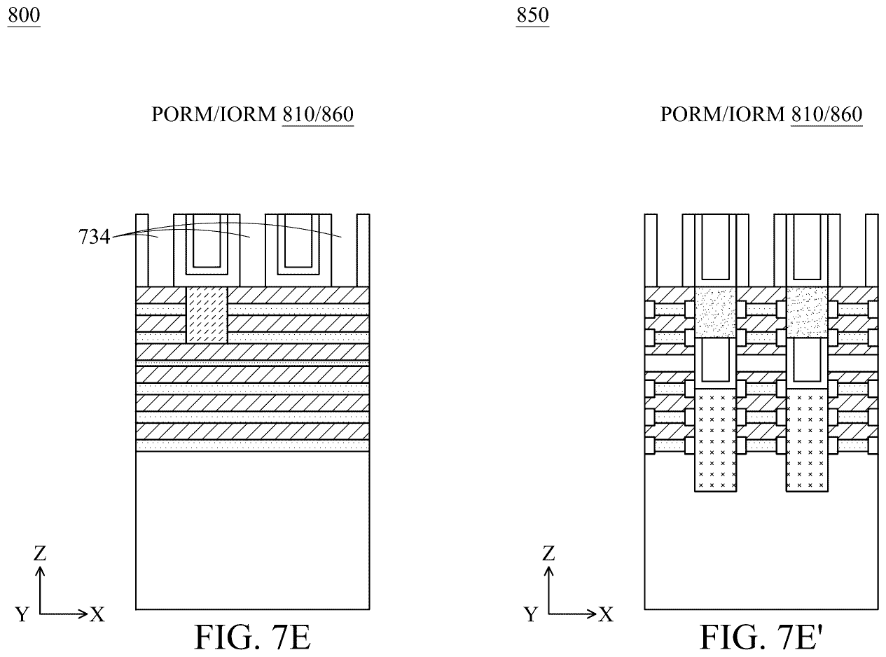

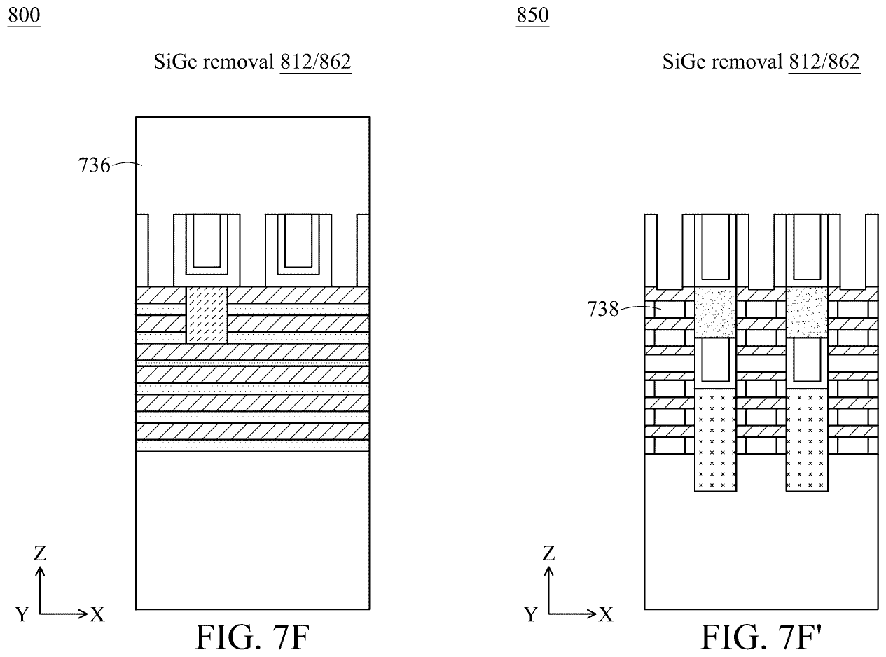

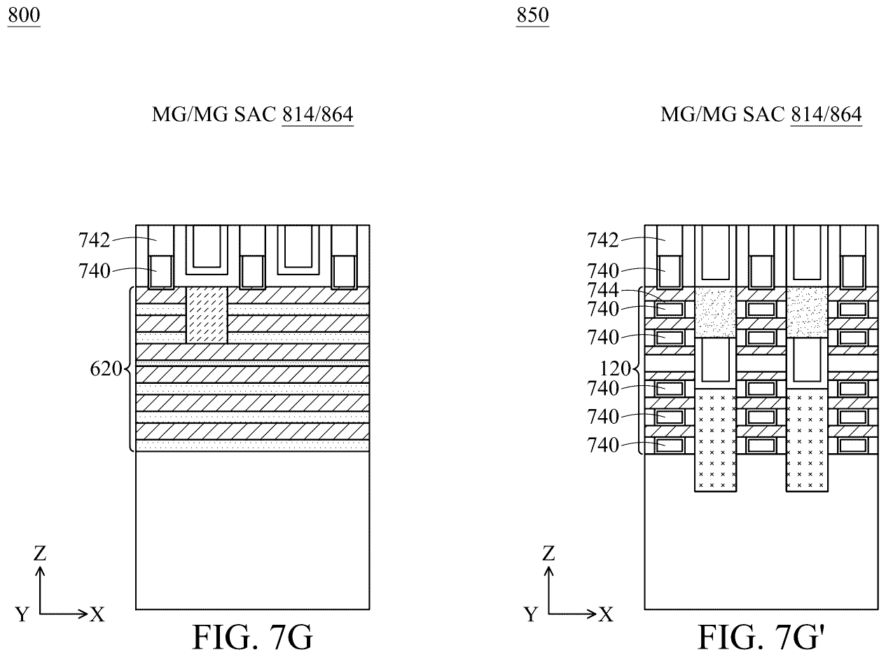

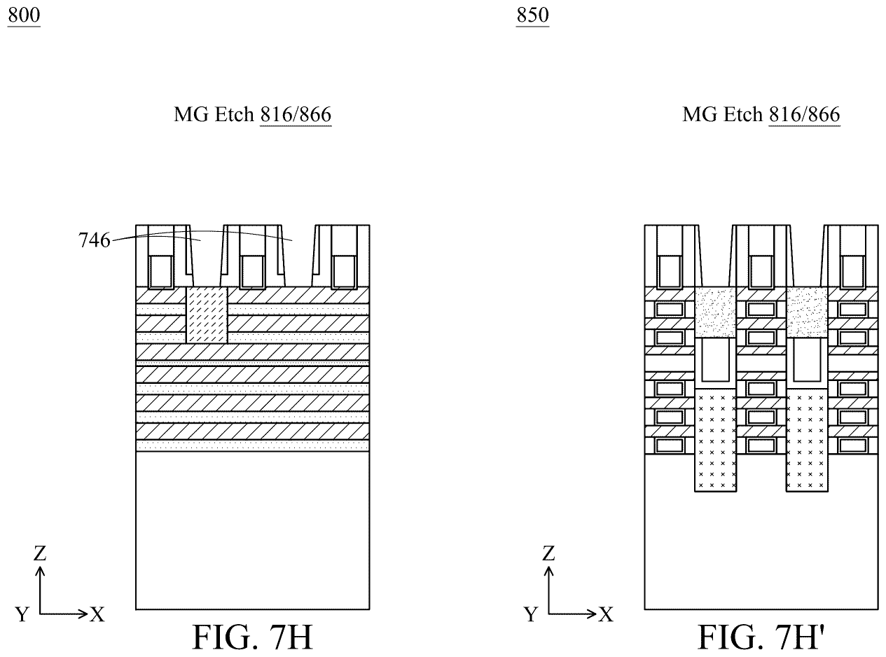

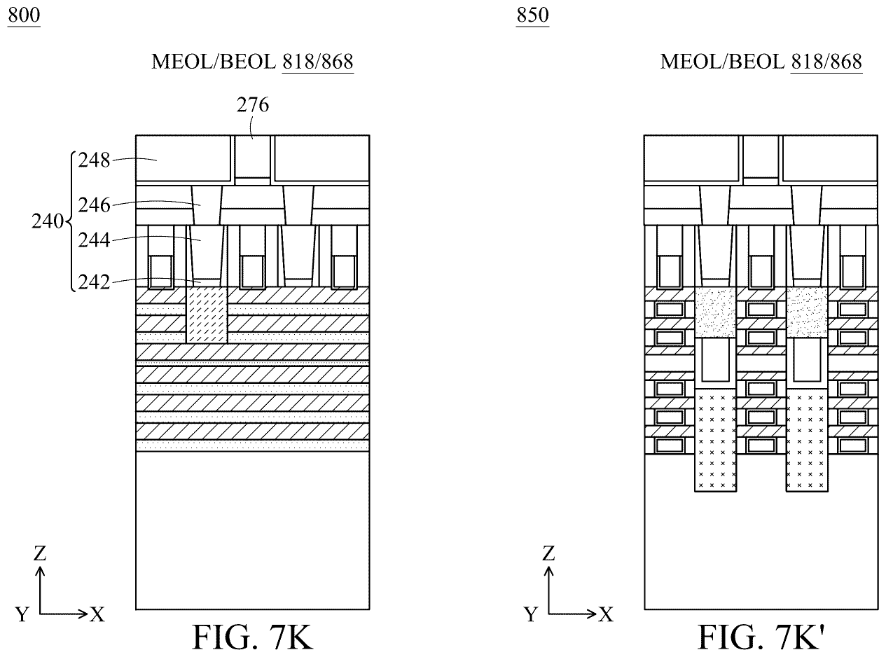

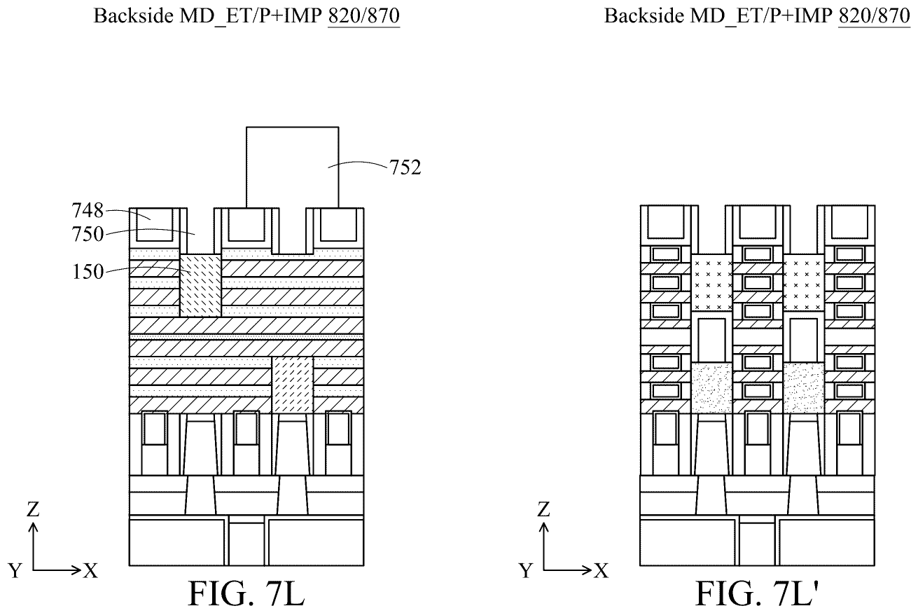

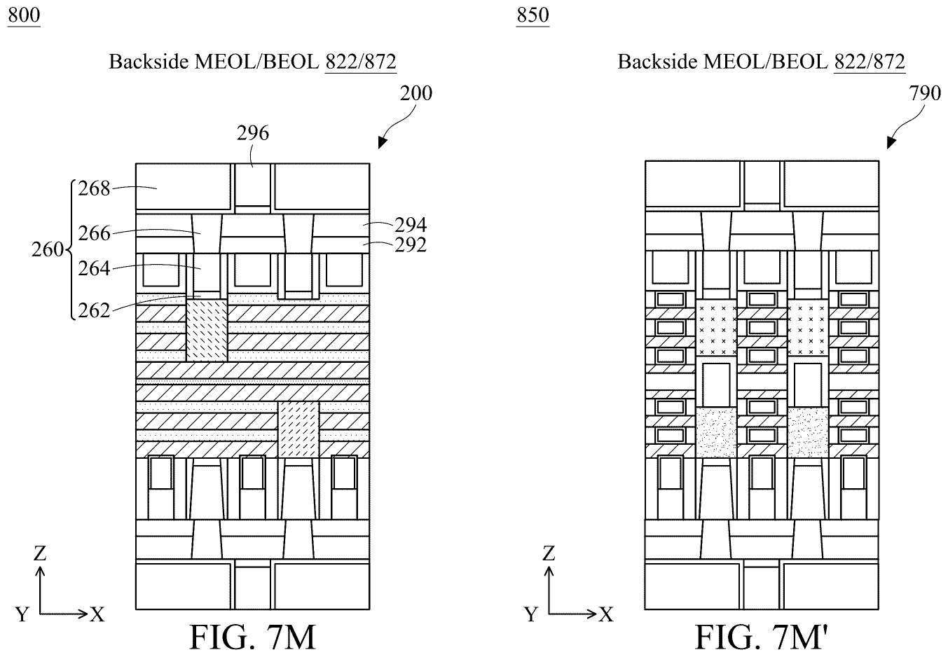

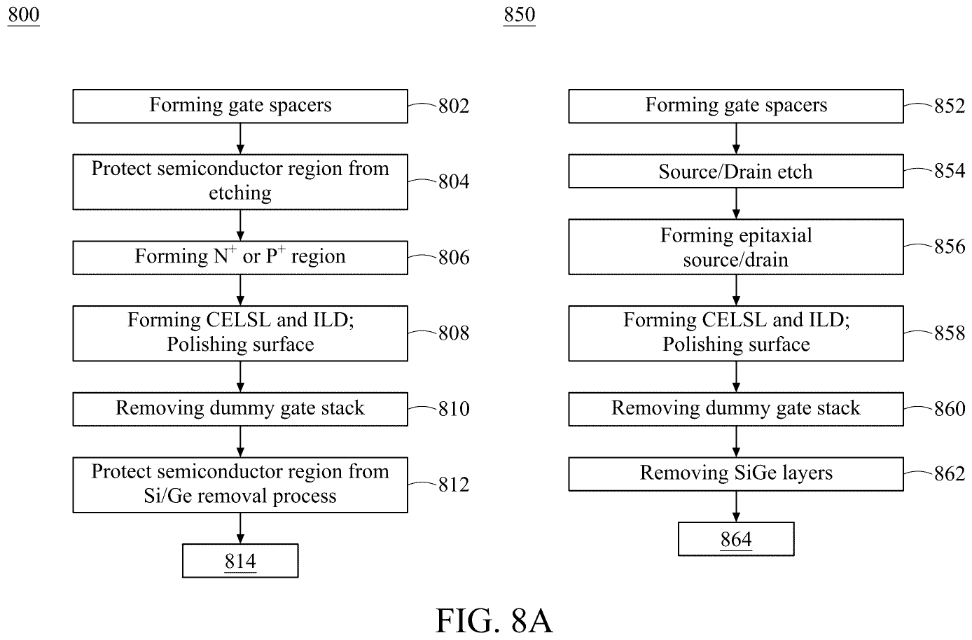

In certain further embodiments, a device such as those illustrated above can be fabricated by a process illustrated in FIGS. 6, 7A-H, K, L, and M, and 7A′-H′, K′, L′, and M′, and outline in FIGS. 8A and 8B. FIG. 6 illustrates starting structure 600 that is common to both the process 800 (FIGS. 8A and 8B) for fabricating a diode and the process 850 (FIGS. 8A and 8B) for fabricating a CFET. FIGS. 7A-H, K, L, and M illustrate the structures at the respective steps of the process 800; FIG. 7A′-H′, K′, L′, and M′ illustrate the structures at the respective steps of the process 800.

It is noted that, although FIGS. 7A-H, K, L, and M, and 7A′-H′, K′, L′, and M′, and outline in FIGS. 8A and 8B illustrate and outline the processes for fabricating a diode and a CFET substantially in parallel, the two devices can be fabricated substantially together or independently.

The process for fabricating a diode according to certain embodiments disclosed in the present disclosure have a number of steps in common with the certain processes for fabricating CFETs. Examples of processes for fabricating CFETs, some including the steps of obtaining the starting structure 600 shown in FIG. 2, can be found in the U.S. Pat. Nos. 12,119,271, 12,131,954, and 12,132,079. The U.S. Pat. Nos. 12,119,271, 12,131,954, and 12,132,079 are hereby incorporated in the present disclosure by reference.

FIG. 6 schematically illustrates a common starting structure 600 for fabricating a diode as well as a CFET according to some embodiments. The structure 600 includes a substrate 610, which may be a Si wafer laterally extending substantially in the x-y plane. Strips, or fins, 612 are formed on the substrate 610 vertically substantially in the z-x planes and each includes a base portion 614 and a multilayer stack 620. The base portions 614 and the substrate 610 are covered by an isolation regions 640. The tops of the isolation regions 640 and the multilayer stack 620 are covered by dummy gate stack 650, which in this example includes a dummy gate dielectric layer 652, a dummy gate layer 654, and a mask layer 656.

The multilayer stack 620 in this example includes semiconductor sheets of alternating composition. In this example, the semiconductor sheets 622 are silicon (Si), and the semiconductor sheets 622 are made of a silicon-germanium alloy (SiGe). Other compositions can be used depending on application. The multilayer stack 620 in this example further includes a dummy semiconductor layer 626, which in some embodiments is germanium (Ge) or SiGe with a higher Ge content than the SiGe sheets 624. The sheets 622, 624 below the dummy semiconductor layer 626 (frontside sheets) can be substantially intrinsic, or at least some of the frontside sheets, such as the Si sheets 622, can be doped, such as n-doped. Likewise, the sheets 622, 624 above the dummy semiconductor layer 626 (backside sheets) can be substantially intrinsic, or at least some of the frontside sheets, such as the Si sheets 122, can be doped, such as p-doped. The doping can be done as the sheet 622, 624 are formed or by other methods, such ion implantation.

The common starting structure 600 can used to fabricate both diodes and CFETs in this example. For example, both diodes and CFETs can be fabricated on the same multilayer stack 620 or different multilayer stacks 620.

The illustrations in FIGS. 7A-H, K, L, and M, and 7A′-H′, K′, L′, and M′ show cross-sections A-A′ labelled in FIG. 6, i.e., cross-sections in a z-x plane taken through a stripe 612.

Referring to FIGS. 7A, 7A′, and 8A, in steps 802 and 852, channels are etched in the dummy gate stack 650, and a gate spacer layer 702 is deposited on the remaining portions of the dummy gate stack 650 for both the diode fabrication process 800 and CFET fabrication process 850.

Referring to FIGS. 7B, 7B′, and 8A, in steps 804 and 854, source and drain channels 706 are etched through the multilayer stack 620 for the CFET fabrication process 850 but not for the diode fabrication process 800. For the diode fabrication process 800, the device area is protected from etching by a protective layer, such as a photoresist layer 702.

Referring to FIGS. 7C, 7C′, and 8A, in steps 806 and 856, for the diode fabrication process 800, ion implantation (in this example N⁺) is carried out in one of the channels in the dummy gate stack 650 to form one electrode region of the diode; the other channel is covered by a hard mask 708 to prevent implantation under that channel.

For the CFET fabrication process 850, the semiconductor layers 624 are partially removed by, for example, etching, and the removed spaces are filled with an insulating material to form spacers 712. Further, the dummy semiconductor layer 626 is completely removed by, for example, etching, and the removed space is filled with the insulating material for form an isolation layer 726. The source/drain regions 710 for the backside transistor of the CFET is formed in the channels 706. Thereafter, contact etch stop layers (CESLs) 716 and interlayer dielectric (ILD) layers 718 are formed on top of the source/drain regions. Thereafter, the source/drain regions 714 for the frontside transistor of the CFET is formed.

Referring to FIGS. 7D, 7D′, and 8A, for both the diode fabrication process 800 and CFET fabrication process 850, in steps 808 and 858, CESLs 730 and ILD layers 732 are formed in the channels in the dummy gate stack 650, and top of the structure is planarized by, for example, chemical-mechanical polishing (CMP).

Referring to FIGS. 7E, 7E′, and 8A, for both the diode fabrication process 800 and CFET fabrication process 850, in steps 810 and 860, the remaining portions of the dummy stack 650 are removed by, for example, etching process(es) known as PORM or IORM to form openings 734 on top of the multilayer stack 620.

Referring to FIGS. 7F, 7F′, and 8A, in steps 812 and 862, for the CFET fabrication process 850, the remainder of the semiconductor layers 624 are removed by, for example etching, to form openings 738. For the diode fabrication process 800, a protective layer, such as a photoresist layer 736, is applied to prevent any removal of materials.

Referring to FIGS. 7G, 7G′, and 8B, in steps 814 and 864, for both the diode fabrication process 800 and CFET fabrication process 850, a metal gates (MG) 740 and self-alignment gate cap (MG SAC) 742 are formed in the opening 734 on top of the multilayer stack 650. Additionally, for the CFET fabrication process 850, gate isolation layers 744 are deposited around the semiconductor layers 622 in the openings resulting from the removal of the semiconductor layers 624. The MG 740 is also formed in the remaining space vacated by the semiconductor layers 624. Each gate 740 thus surrounds the FET channels formed by the semiconductor layers 622.

Referring to FIGS. 7H, 7H′, and 8B, in steps 816 and 866, for both the diode fabrication process 800 and CFET fabrication process 850, the CESLs 730 and ILD layers 732 are removed by, for example, etching to for openings 746.

Referring to FIGS. 7K, 7K′, and 8B, in steps 818 and 868, for both the diode fabrication process 800 and CFET fabrication process 850, a first (frontside) conductive contact structure 240 is formed. The frontside conductive contact structure 240 in this example includes a metal-semiconductor alloy layer 242, vias 244, 246 and a contact pad 248. Additionally, frontside isolation regions 272, 274, 276 are formed above the layer containing the gate spacers and openings 746. Metal-semiconductor alloy layer 242 and vias 244 are formed in the openings 746; vias 246 are formed through the isolation regions 272, 274; and the isolation region 276 is formed between the contact pads 248.

Referring to FIGS. 7L, 7L′, and 8B, in steps 820 and 870, for both the diode fabrication process 800 and CFET fabrication process 850, the lower portion 614 of the strip, or fin, 612 is removed by, for example, polishing and/or etching. Gate structures 748, similar to those 740 are then formed in steps similar to those in steps 814, 864. Additionally, openings 750 are formed in MD etch steps similar to those in steps 816, 866.

Additionally, for the diode fabrication process 800, ion implantation (in this example P⁺) is carried out in one of the openings 750 to form backside electrode region of the diode; the other opening 750 is covered by a hard mask 752 to prevent implantation under that channel.

Finally, Referring to FIGS. 7M, 7M′, and 8B, in steps 822 and 872, for both the diode fabrication process 800 and CFET fabrication process 850, a second (backside) conductive contact structure 260 is formed. The backside conductive contact structure 260 in this example includes a metal-semiconductor alloy layer 262, vias 264, 266 and a contact pad 268. Additionally, backside isolation regions 292, 294, 296 are formed below (relative to the orientation at the start of the processes 800, 850) the layer containing the gate structures 748 and openings 750. Metal-semiconductor alloy layer 262 and vias 264 are formed in the openings 750; vias 246 are formed through the isolation regions 292, 274; and the isolation region 296 is formed between the contact pads 268.

At the ends of the processes 800, 850, a diode 200 illustrated in FIG. 2, as well as a CFET 790, are fabricated.

In other example embodiments (not shown in the drawings), both the frontside and backside dope regions are connected respective conductive contact structures disposed on the same side (frontside or backside) of the semiconductor layer. For example, the doped region 150 in the backside of the diode 200 shown in FIG. 2 can be connected to a frontside contact pad through a via running though the thickness of the multilayer stack 220.

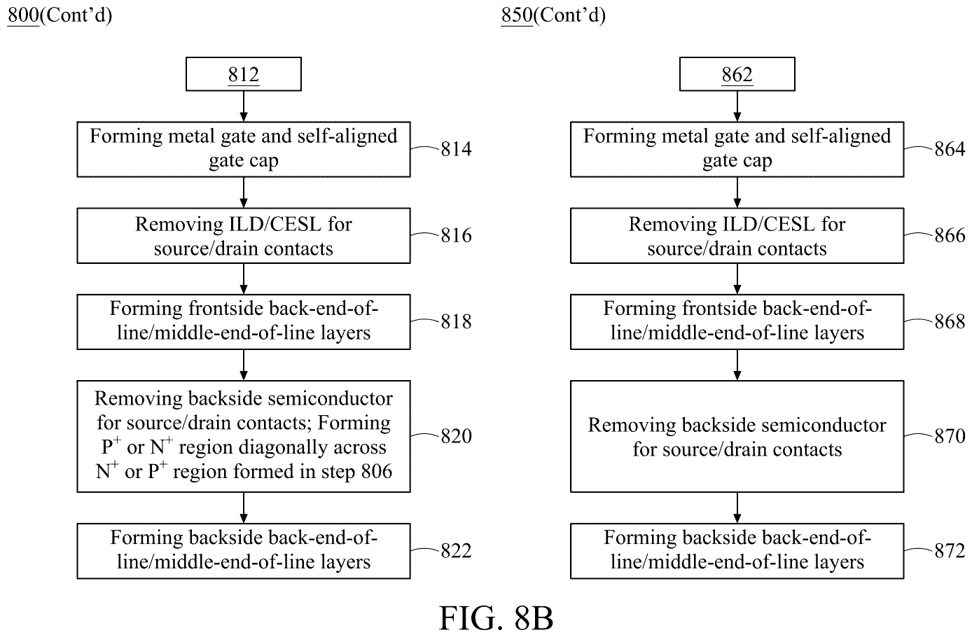

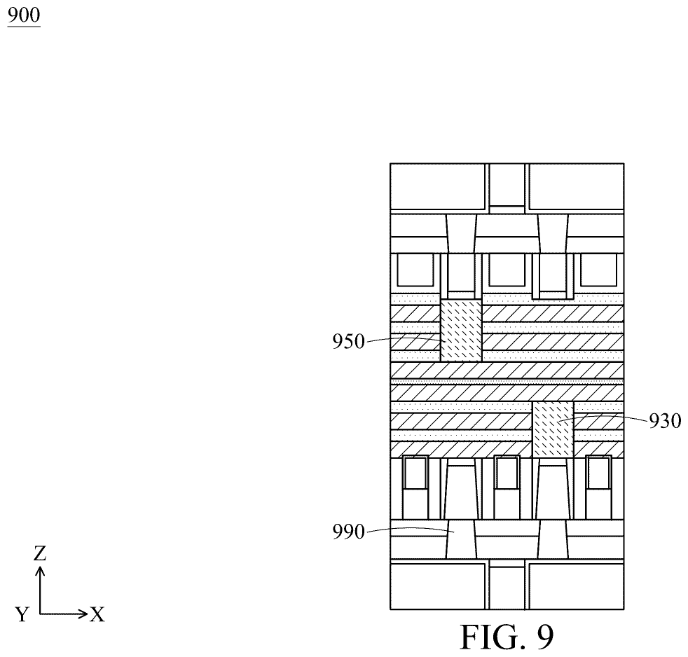

The principles embodied in the examples disclosed above can be applied to additional embodiments. For example, in an example schematically illustrated in FIG. 9, other devices can be fabricated in similar fashions as illustrated above. For example, a bipolar junction transistor (BJT) can be fabricated substantially as illustrated above for a PIN diode. For example, instead of frontside and backside electrodes 930, 950 being opposite types (e.g., N⁺ for frontside and P⁺ for backside), the ion implantations in steps 806, 820 can be of the same type (both N⁺ or both P⁺). Further step(s) (not illustrated) can be carried out to form (e.g., by ion implantation) a third doped region of opposite type than the regions 930, 950 between the regions 930, 950 and connect the third region with a conductive contact structure, such as the conductive contact structure 990.

In summary, according to aspects of the present disclosure, an integrated circuit device includes: a semiconductor layer portion having a frontside surface and a backside surface, spaced apart from the frontside surface in a first direction, the frontside and backside surfaces each extending in at least a second direction transverse to the first direction; and a first diode, which include: a first doped region disposed in the semiconductor layer portion; a second doped region disposed in the semiconductor layer portion and apart from the first doped region; a first conductive contact structure connected to the first doped region; and a second conductive contact structure connected to the second doped region; the first doped region being closer to the top surface than the second doped region is, the first and second doped regions being offset from each other in the second direction.

According to certain other aspects of the present disclosure, an integrated circuit (IC) device includes: a semiconducting layer having a top surface and a bottom surface, the top and bottom surfaces being oriented substantially in a first direction and extend substantially in at least a second direction transverse to the first direction; a complementary field-effect transistor (CFET) formed in the semiconductor layer and comprising a top FET and a bottom FET disposed below the top FET along the first direction; and a semiconductor device formed in the semiconductor layer and including: a first doped region disposed in the semiconductor layer portion; a second doped region disposed in the semiconductor layer portion and apart from the first doped region; a first conductive contact structure connected to the first doped region; and a second conductive contact structure connected to the second doped region; the first doped region being disposed at the top surface, and the second doped region being dispose at the bottom surface, the first and second doped regions being offset from each other in the second direction.

According to certain further aspects of the present disclosure, a method includes: forming a semiconductor layer having a top surface and a bottom surface and comprising a stacked sequence of semiconductor layers in a first direction, the semiconductor layer extends in at least a second direction transverse to the first direction; forming a first semiconductor device in the semiconductor layer by: doping a first portion of the semiconductor layer at the top of the stacked sequence of semiconductor layers; and doping a second portion of the semiconductor layer at the bottom of the stacked sequence of semiconductor layers, the second portion being offset from the first portion in a direction substantially parallel to the semiconductor layers; and forming a second semiconductor device comprising a CFET by forming a plurality of channels, each from a respective one of a subset of the stacked sequence of semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit device, comprising:
a semiconductor layer portion having a frontside surface and a backside surface, spaced apart from the frontside surface in a first direction, the frontside and backside surfaces each extending in at least a second direction transverse to the first direction; and
a first diode, comprising:
a first doped region disposed in the semiconductor layer portion;
a second doped region disposed in the semiconductor layer portion and apart from the first doped region;
a first conductive contact structure connected to the first doped region; and
a second conductive contact structure connected to the second doped region;
the first doped region being closer to the top surface than the second doped region is, the first and second doped regions being offset from each other in the second direction.

2. The integrated circuit device of claim 1, wherein:
the semiconductor layer comprises a multilayer stack, the layers having alternating compositions;
the first doped region is an n-type or p-type doped region and disposed at the frontside surface of the multilayer stack; and
the second doped region is a doped region of the opposite type of the first doped region and disposed at the backside surface of the multilayer stack.

3. The integrated circuit device of claim 2, further comprising a field-effect transistor (FET) formed in the semiconductor layer portion, the FET and the first diode sharing at least a subset of the layers of the multilayer stack.

4. The integrated circuit device of claim 3, wherein:
alternate layers in the multilayer stack are layers of semiconductor of a first kind; and
the FET comprises a plurality of channels made of the respective layers of the semiconductor of the first kind.

5. The integrated circuit device of claim 1, further comprising a complementary field-effect transistor (CFET) formed in a first portion of the semiconductor layer portion and comprising a pair of FETs stacked in the first direction,
wherein the semiconductor layer comprises a multilayer stack comprising a first plurality of layers of semiconductor of a first kind,
the CFET including a plurality of channels, each channel comprising a portion of a respective one of the first plurality of layers of semiconductors.

6. The integrated circuit device of claim 5, wherein:
the multilayer stack comprises a second portion further comprises a second plurality of layers, arranged in an alternate stacking sequence with the first plurality of layers,
the first diode is formed in the second portion.

7. The integrated circuit device of claim 6, wherein the first plurality of layers are silicon (Si) layers, and the second plurality of layers are layers of a silicon-germanium alloy.

8. The integrated circuit device of claim 1, wherein the first contact connection structure comprises a first contact pad dispose at the frontside surface of the semiconductor layer, and the second contact connection structure comprises second contact pad dispose at the backside surface of the semiconductor layer.

9. The integrated circuit device of claim 1, wherein the semiconductor layer portion comprises:
a first plurality of layers;
a second plurality of layers; and
a third layer;
the first and second pluralities of layers and the third layer formed in a stacking sequence, the third layer dividing the first and second plurality of layers,
the first plurality of layers including alternating layers of a first semiconductor and a second semiconductor;
the second plurality of layers including alternating layers of the first semiconductor and the second semiconductor; and
the third layer being a third semiconductor.

10. The integrated circuit device of claim 9, wherein:
the first semiconductor is silicon (Si);
the second semiconductor is a silicon-germanium alloy (SiGe); and
the third semiconductor is Ge or a SiGe a higher Ge content than the second semiconductor.

11. The integrated circuit device of claim 1, wherein the first and second doped regions have different sizes.

12. The integrated circuit device of claim 1, further comprising a second diode, comprising:
a third doped region disposed in the semiconductor layer portion;
a fourth doped region disposed in the semiconductor layer portion and apart from the third doped region;
a third conductive contact structure connected to the third doped region; and
a fourth conductive contact structure connected to the fourth doped region;
the third doped region being closer to the frontside surface than the four doped region is, the third and fourth doped regions being offset from each other in the second direction,
wherein:
the offset between the third and fourth doped regions in the second direction is different from the offset between the first and second doped regions in the second direction, or
the first and third doped regions have difference sizes.

13. An integrated circuit (IC) device, comprising:
a semiconducting layer having a top surface and a bottom surface, the top and bottom surfaces being oriented substantially in a first direction and extend substantially in at least a second direction transverse to the first direction;
a complementary field-effect transistor (CFET) formed in the semiconductor layer and comprising a top FET and a bottom FET disposed below the top FET along the first direction; and
a semiconductor device formed in the semiconductor layer and comprising:
a first doped region disposed in the semiconductor layer portion;
a second doped region disposed in the semiconductor layer portion and apart from the first doped region;
a first conductive contact structure connected to the first doped region; and
a second conductive contact structure connected to the second doped region;
the first doped region being disposed at the top surface, and the second doped region being dispose at the bottom surface, the first and second doped regions being offset from each other in the second direction.

14. The integrated circuit (IC) device of claim 13, wherein the first doped region is an n-dope or p-doped region, and the second doped region is a doped region of opposite dope type to the first doped region.

15. The integrated circuit (IC) device of claim 13, wherein the first doped region is an n-dope or p-doped region, and the second doped region is a doped region of the same dope type as the first doped region.

16. The integrated circuit (IC) device of claim 15, wherein the semiconductor device further comprises a third doped region of opposite type to the first and second doped regions.

17. The integrated circuit (IC) device of claim 13, wherein the semiconductor layer comprises a first plurality of layers of a first semiconductor, wherein the CFET comprises a plurality of channels, each comprising a portion of a respective layer of the first semiconductor.

18. A method, comprising:
forming a semiconductor layer having a top surface and a bottom surface and comprising a stacked sequence of semiconductor layers in a first direction, the semiconductor layer extends in at least a second direction transverse to the first direction;
forming a first semiconductor device in the semiconductor layer by:
doping a first portion of the semiconductor layer at the top of the stacked sequence of semiconductor layers; and
doping a second portion of the semiconductor layer at the bottom of the stacked sequence of semiconductor layers, the second portion being offset from the first portion in a direction substantially parallel to the semiconductor layers; and
forming a second semiconductor device comprising a CFET by forming a plurality of channels, each from a respective one of a subset of the stacked sequence of semiconductor layers.

19. The method of claim 18, wherein the forming the first semiconductor device and forming the second semiconductor device are carried out substantially at the same time.

20. The method of claim 18, further comprising forming a first conductive contact structure at the top surface of the semiconductor layer to connect to the first doped region and forming a second conductive contact structure at the top surface of the semiconductor layer to connect to the second doped region.
